(19) United States
(12) Patent Application Publication
(10) Pub. No.: US 2026/0173957 A1
(43) Pub. Date: Jun. 18, 2026

(54) PACKAGE COMPRISING A STACK OF INTEGRATED DEVICES AND A PLURALITY OF WIRE BONDS

(71) Applicant: QUALCOMM Incorporated, San Diego, CA (US)

(72) Inventors: Yujen CHEN, Taichung (TW); Aniket PATIL, San Diego, CA (US); Yangyang SUN, San Diego, CA (US)

(21) Appl. No.: 18/984,801

(22) Filed: Dec. 17, 2024

(51) Int. Cl. H01L 25/16; H01L 21/48; H01L 21/56; H01L 23/00; H01L 23/498; H01L 25/00; H10B 80/00

(52) U.S. Cl. CPC H10W 90/00; H10B 80/00; H10W 70/093; H10W 74/016; H10W 90/701; H10W 90/724; H10W 90/732; H10W 90/754

(57) ABSTRACT

A package comprising a metallization portion; a first integrated device coupled to the metallization; a second integrated device coupled to the first integrated device through an adhesive; a first plurality of wire bonds coupled to the second integrated device and the metallization portion; and an encapsulation layer at least partially encapsulating the first integrated device, the second integrated device and the first plurality of wire bonds.

### FIELD

Various features relate to packages with a stack of integrated devices.

### BACKGROUND

A package may include a substrate and integrated devices. These components are coupled together to provide a package that may perform various electrical functions. There is an ongoing need to provide better performing packages. Moreover, there is also an ongoing need to reduce and/or minimize the overall size of the packages.

### SUMMARY

Various features relate to packages with a stack of integrated devices.

One example provides a package comprising a metallization portion; a first integrated device coupled to the metallization; a second integrated device coupled to the first integrated device through an adhesive; a first plurality of wire bonds coupled to the second integrated device and the metallization portion; and an encapsulation layer at least partially encapsulating the first integrated device, the second integrated device and the first plurality of wire bonds.

Another example provides a method for fabricating a package. The method provides a first integrated device. The method couples a second integrated device to the first integrated device through an adhesive. The method couples a first plurality of wire bonds to the second integrated device. The method forms an encapsulation layer that least partially encapsulates the first integrated device, the second integrated and the first plurality of wire bonds. The method forms a metallization portion that is coupled to the first integrated device and the first plurality of wire bonds.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary cross sectional profile view of a package that includes a stack of integrated devices and a plurality of wire bonds.

FIG. 2 illustrates an exemplary cross sectional plan view of a package that includes a stack of integrated devices and a plurality of wire bonds.

FIG. 3 illustrates an exemplary cross sectional plan view of a package that includes a stack of integrated devices and a plurality of wire bonds.

FIGS. 4A-4F illustrate an exemplary sequence for fabricating a package that includes a stack of integrated devices and a plurality of wire bonds.

FIG. 5 illustrates an exemplary flow diagram of a method for fabricating a package that includes a stack of integrated devices and a plurality of wire bonds.

FIGS. 6A-6B illustrate an exemplary sequence for fabricating a metallization portion.

FIG. 7 illustrates an exemplary flow chart of a method for fabricating a metallization portion.

FIG. 8 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown as block diagrams in order to avoid obscuring the aspects in unnecessary detail. In other instances, well-known circuits, structures and techniques may not be shown in detail in order not to obscure the aspects of the disclosure.

The present disclosure describes a package comprising a metallization portion; a first integrated device coupled to the metallization; a second integrated device coupled to the first integrated device through an adhesive; a first plurality of wire bonds coupled to the second integrated device and the metallization portion; and an encapsulation layer at least partially encapsulating the first integrated device, the second integrated device and the first plurality of wire bonds. The use of the plurality of wire bonds may help reduce the pitch of interconnects of the package, since wire bonds have relatively thin diameters and high aspect ratios. This can help reduce the overall size and/or footprint of the package, while also providing high capacity bandwidth for the package.

### Exemplary Package Comprising a Stack of Integrated Devices and Wire Bonds

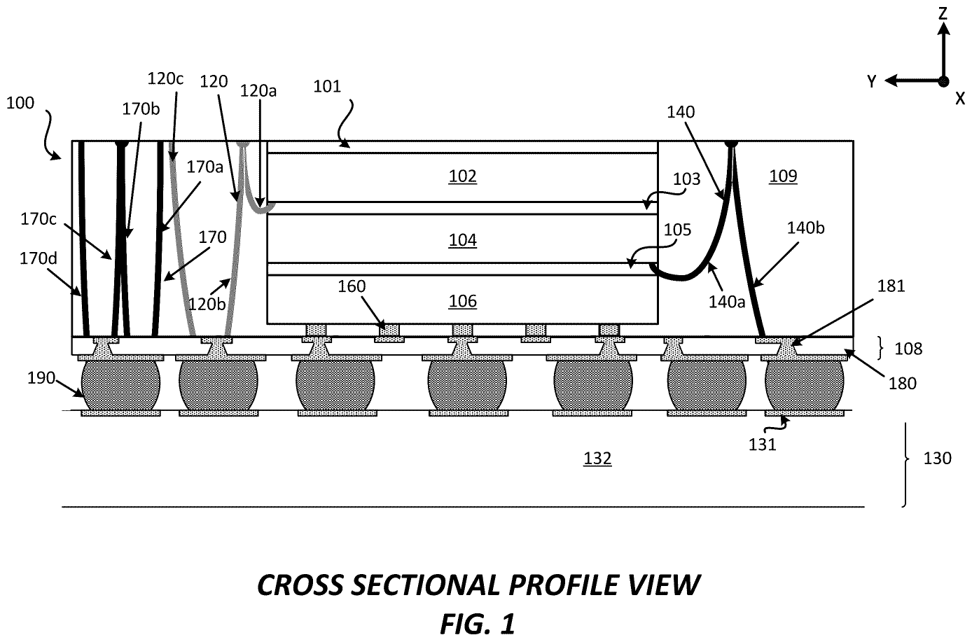

FIG. 1 illustrates a cross sectional profile view of a package 100 that includes a plurality of integrated devices and a plurality of wire bonds. The package 100 is coupled to a board 130 through a plurality of solder interconnects 190. The board 130 includes at least one board dielectric layer 132 and a plurality of board interconnects 131. The board 130 may include a printed circuit board (PCB). In some implementations, the package 100 may be coupled to a substrate (e.g., laminated substrate, coreless substrate, cored substrate) instead of the board 130.

The package 100 includes an integrated device 102, an integrated device 104, an integrated device 106, an adhesive 101, an adhesive 103, an adhesive 105, a plurality of wire bonds 120, a plurality of wire bonds 140, a plurality of wire bonds 170, a metallization portion 108, and an encapsulation layer 109. The encapsulation layer 109 may at least partially encapsulate the integrated device 102, the integrated device 104, the integrated device 106, the adhesive 101, the adhesive 103, the adhesive 105, the plurality of wire bonds 120, the plurality of wire bonds 140 and/or the plurality of wire bonds 170. The encapsulation layer 109 may include a mold, a resin, an epoxy and/or a filler. The encapsulation layer 109 is coupled to the metallization portion 108.

The metallization portion 108 may include at least one dielectric layer 180 and a plurality of metallization interconnects 181. The plurality of solder interconnects 190 may be coupled to the plurality of metallization interconnects 181. The metallization portion 108 may one or more metal layers (e.g., two or more metal layers).

The integrated device 102, the integrated device 104 and the integrated device 106 may be arranged as a stack of integrated devices (e.g., vertical stack of integrated devices). Different implementations of the stack of integrated devices may have different numbers of integrated devices. The integrated device 102 and/or the integrated device 104 may include a memory (e.g., memory chip). For example, one or more of the integrated device 102 and/or the integrated device 104 may be a memory device (e.g., memory chip, memory die). The integrated device 106 may include a processor device. An adhesive 101 (e.g., die attach film (DAF), film over wire (FOW)) is coupled to the integrated device 102 (e.g., coupled to a back side of the integrated device 102). A front side of the integrated device 102 is coupled to a back side of the integrated device 104 through an adhesive 103 (e.g., die attach film, film over wire). The adhesive 103 is located between the integrated device 102 and the integrated device 104. The adhesive 103 is coupled to the integrated device 102 and the integrated device 104. A front side of the integrated device 104 is coupled to a back side of the integrated device 106 through an adhesive 105 (e.g., die attach film, film over wire). The adhesive 105 is located between the integrated device 104 and the integrated device 106. The adhesive 105 is coupled to the integrated device 104 and the integrated device 106. The integrated device 106 is coupled to the metallization portion 108. For example, the integrated device 106 is coupled to the metallization portion 108 through a plurality of pillar interconnects 160. The plurality of pillar interconnects 160 may be coupled to the plurality of metallization interconnects 181 of the metallization portion 108. In some implementations, an electrical connection between the integrated device 106 and the metallization portion 108 is free of solder. In some implementations, an electrical connection between the integrated device 106 and the metallization portion 108 bypasses wire bonds.

The plurality of wire bonds 120 are coupled to the metallization portion 108. The plurality of wire bonds 120 are coupled to the integrated device 102 and at least one metallization interconnect from the plurality of metallization interconnects 181. The plurality of wire bonds 120 may include a wire bond 120a, a wire bond 120b and a wire bond 120c. The wire bond 120a and the wire bond 120b may be considered as one wire bond or two separate wire bonds that are coupled to each other. There may be a ball bond between the wire bond 120a and the wire bond 120b. The ball bond may be considered part of the plurality of wire bonds 120. The wire bond 120a is coupled to the integrated device 102 (e.g., coupled to and touching a front side of the integrated device 102, coupled to and touching a pad of the integrated device 102). The wire bond 120a may be coupled to the front side of the integrated device 102 through a ball bond. The wire bond 120b is coupled to and touching a metallization interconnect from the plurality of metallization interconnects 181. An electrical path between the integrated device 102 and the board 130 may include the wire bond 120a, the wire bond 120b (may also include the ball bond between the wire bond 120a and the wire bond 120b), metallization interconnects from the plurality of metallization interconnects 181, a solder interconnect from the plurality of solder interconnects 190 and a board interconnect from the plurality of board interconnects 131. In some implementations, the wire bond 120c may be a dummy wire bond that is not electrically coupled to the integrated device 102. In some implementation, the wire bond 120c may be free of electrical connection any integrated device (e.g., free of any electrical connection with the integrated device 102, the integrated device 104 and/or the integrated device 106).

The plurality of wire bonds 140 are coupled to the metallization portion 108. The plurality of wire bonds 140 are coupled to the integrated device 104 and at least one metallization interconnect from the plurality of metallization interconnects 181. The plurality of wire bonds 140 may include a wire bond 140a and a wire bond 140b. The wire bond 140a and the wire bond 140b may be considered as one wire bond or two separate wire bonds that are coupled to each other. There may be a ball bond between the wire bond 140a and the wire bond 140b. The ball bond may be considered part of the plurality of wire bonds 140. The wire bond 140a is coupled to the integrated device 104 (e.g., coupled to and touching a front side of the integrated device 104, coupled to and touching a pad of the integrated device 104). The wire bond 140a may be coupled to the front side of the integrated device 104 through a ball bond. The wire bond 140b is coupled to and touching a metallization interconnect from the plurality of metallization interconnects 181. An electrical path between the integrated device 104 and the board 130 may include the wire bond 140a, the wire bond 140b (may also include the ball bond between the wire bond 140a and the wire bond 140b), metallization interconnects from the plurality of metallization interconnects 181, a solder interconnect from the plurality of solder interconnects 190 and a board interconnect from the plurality of board interconnects 131.

The plurality of wire bonds 170 are coupled to the metallization portion 108. The plurality of wire bonds 170 include a wire bond 170a, a wire bond 170b, a wire bond 170c and a wire bond 170d. The plurality of wire bonds 170 may be coupled to the metallization interconnects from the plurality of metallization interconnects 181 of the metallization portion 108.

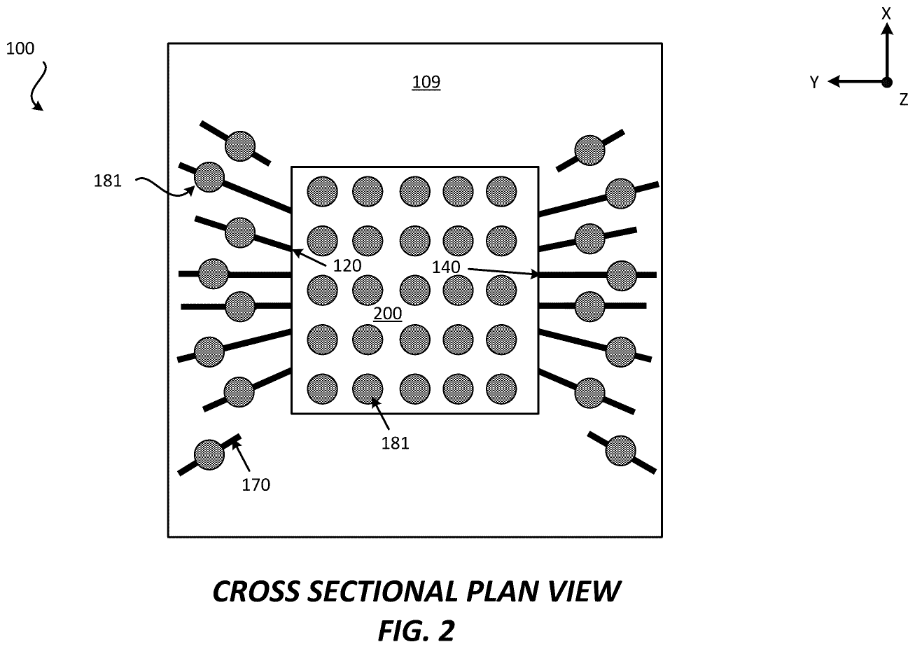

FIG. 2 illustrates a cross sectional plan view of the package 100. The package 100 includes a stack of integrated devices 200, the plurality of wire bonds 120, the plurality of wire bonds 140, the plurality of wire bonds 170, the encapsulation layer 109 and the plurality of metallization interconnects 181. The plurality of metallization interconnects 181 are coupled to the plurality of wire bonds 120, the plurality of wire bonds 140 and/or the plurality of wire bonds 170. It is noted that that in some implementations, the plurality of wire bonds 120, the plurality of wire bonds 140 and/or the plurality of wire bonds 170 may be arranged in an intertwined configuration. It is noted that that in some implementations, portion of the plurality of wire bonds 120, portions of the plurality of wire bonds 140 and/or portions of the plurality of wire bonds 170 may vertically overlap with one another. The stack of integrated devices 200 may include the integrated device 102, the integrated device 104 and the integrated device 106. The stack of integrated devices 200 may also include the adhesive 101, the adhesive 103 and/or the adhesive 105. The stack of integrated devices 200 may be a vertical stack of integrated devices. In some implementations, the stack of integrated devices 200 may be arranged and/or configured such that (i) the front side of the integrated device 102 faces in the direction of the back side of the integrated device 104, and/or (ii) the front side of the integrated device 104 faces in the direction of the back side of the integrated device 106. The stack of integrated devices 200 may include two or more integrated devices. Thus, in some implementations, the stack of integrated devices 200 may include less than three integrated devices or more than three integrated devices.

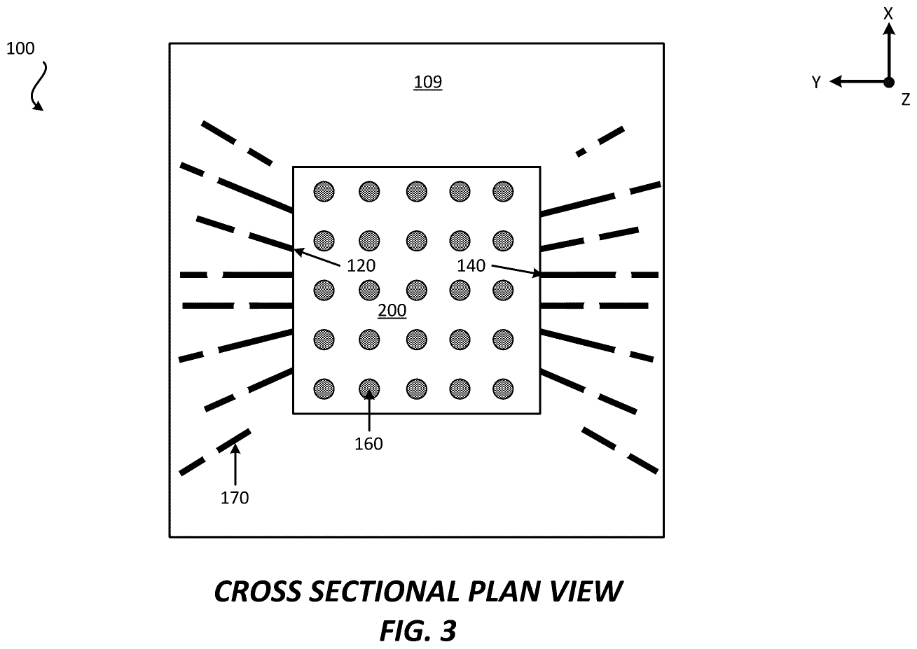

FIG. 3 illustrates a cross sectional plan view of the package 100. FIG. 3 is similar to FIG. 2, but does not illustrate the plurality of metallization interconnects 181. The package 100 of FIG. 3 includes a stack of integrated devices 200, the plurality of wire bonds 120, the plurality of wire bonds 140, the plurality of wire bonds 170, the plurality of pillar interconnects 160 and the encapsulation layer 109. FIG. 3 illustrates that there may be a separation of wire bonds. This may result in dummy wire bonds in the package 100. For example, the wire bond 120c may be separate from the wire bond 120b.

The plurality of wire bonds 120, the plurality of wire bonds 140 and/or the plurality of wire bonds 170 may include wire bonds that touch opposite sides and/or surfaces of the encapsulation layer 109. The use of the plurality of wire bonds 120, the plurality of wire bonds 140 and/or the plurality of wire bonds 170 may help reduce the pitch of interconnects of the package 100, since wire bonds have relatively thin diameters and high aspect ratios. This can help reduce the overall size and/or footprint of the package 100. Moreover, no through encapsulation layer vias or additional metallization interconnects may be necessary, which can help reduce the overall thickness of the package 100 and/or reduce the overall cost of the package 100.

The metallization portion 108 may include a redistribution portion. The plurality of metallization interconnects 181 may include a plurality of redistribution interconnects. A redistribution interconnect may include portions that have a U-shape or V-shape. The terms “U-shape” and “ V-shape” shall be interchangeable. The terms “U-shape” and “V-shape” may refer to the side profile shape of the interconnects, metallization interconnects and/or redistribution interconnects. The U-shape interconnect (e.g., U-shape side profile interconnect) and the V-shape interconnect (e.g., V-shape side profile interconnect) may have a top portion and a bottom portion. A bottom portion of a U-shape interconnect (or a V-shape interconnect) may be coupled to a top portion of another U-shape interconnect (or a V-shape interconnect). In some implementations, a process for fabricating redistribution interconnects may form the U-shape interconnect (or the V-shape interconnect).

An integrated device (e.g., 106) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc . . . ). An integrated device may include an input/output (I/O) hub. An integrated device may include transistors. An integrated device may be an example of an electrical component and/or electrical device.

In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). As mentioned above, using several chiplets that perform several functions may reduce the overall cost of a package relative to using a single chip to perform all of the functions of a package. In some implementations, one or more of the chiplets and/or one of more of integrated devices (e.g., 106) described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap width between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node. To optimize the cost of a package, some of the functions can be implemented in different integrated devices and/or chiplets, where different integrated devices and/or chiplets may be fabricated using different technology nodes to reduce overall costs. For example, functions that require the use of the most advanced technology node may be implemented in an integrated device, and functions that can be implemented using a less advanced technology node can be implemented in another integrated device and/or one or more chiplets. One example, would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

The package (e.g., 100) may be implemented in a radio frequency (RF) package. The RF package may be a radio frequency front end (RFFE) package. A package (e.g., 100) may be configured to provide Wireless Fidelity (WiFi) communication and/or cellular communication (e.g., 2G, 3G, 4G, 5G, 6G). The packages (e.g., 100) may be configured to support Global System for Mobile (GSM) Communications, Universal Mobile Telecommunications System (UMTS), and/or Long-Term Evolution (LTE). The packages (e.g., 100) may be configured to transmit and receive signals having different frequencies and/or communication protocols.

### Exemplary Sequence for Fabricating a Package Comprising a Stack of Integrated Devices and Wire Bonds

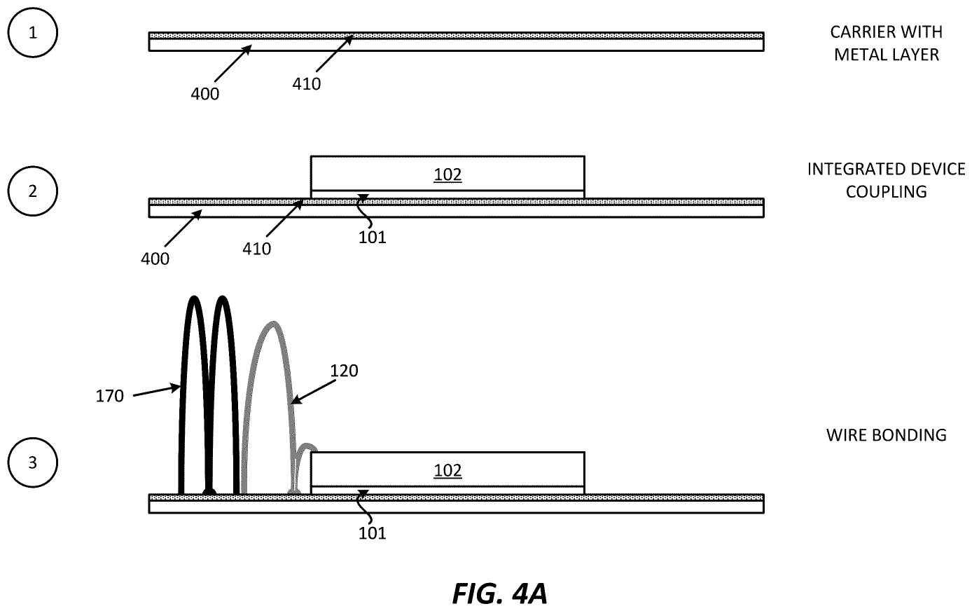

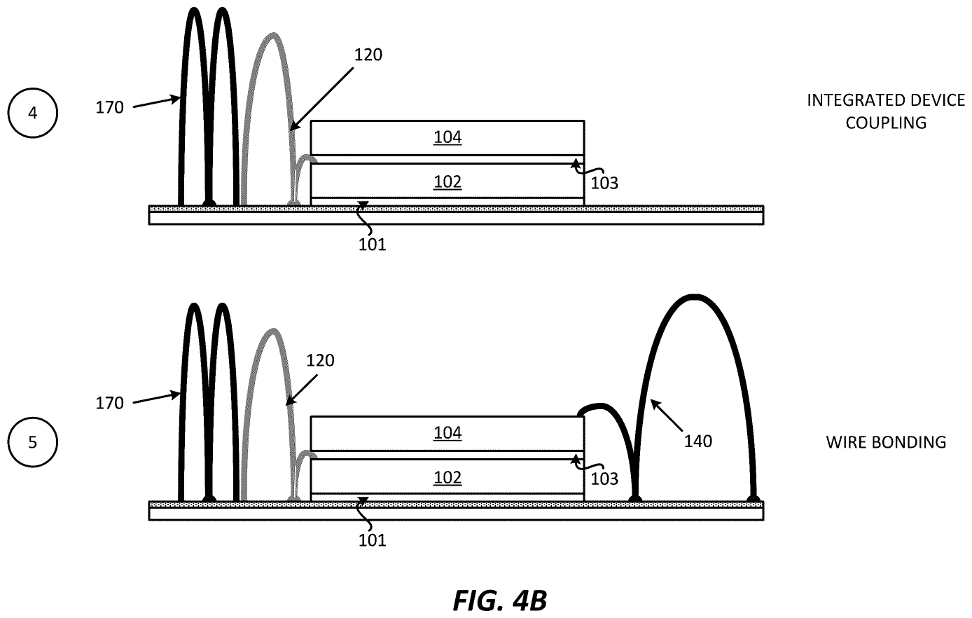

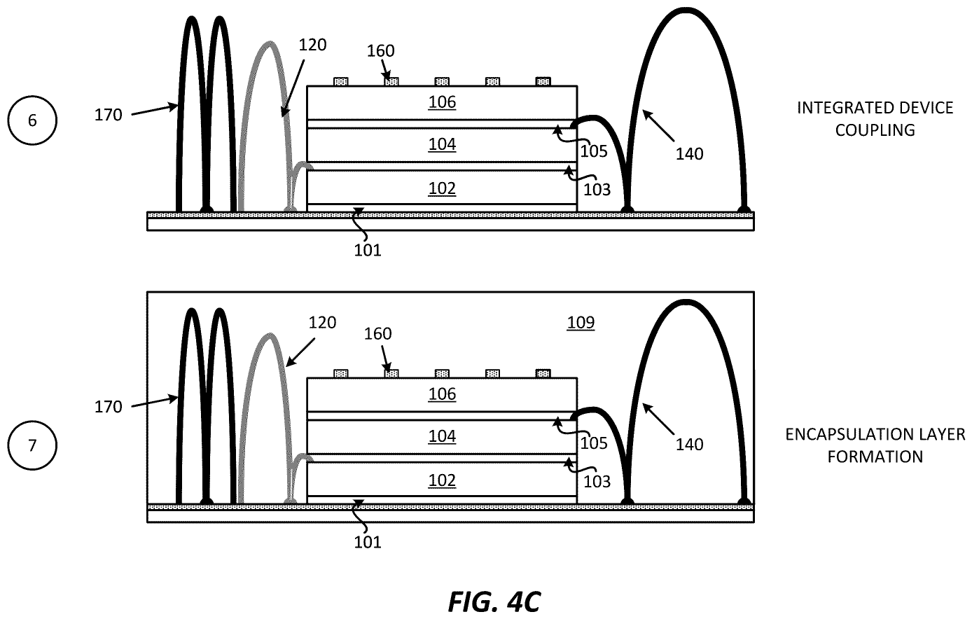

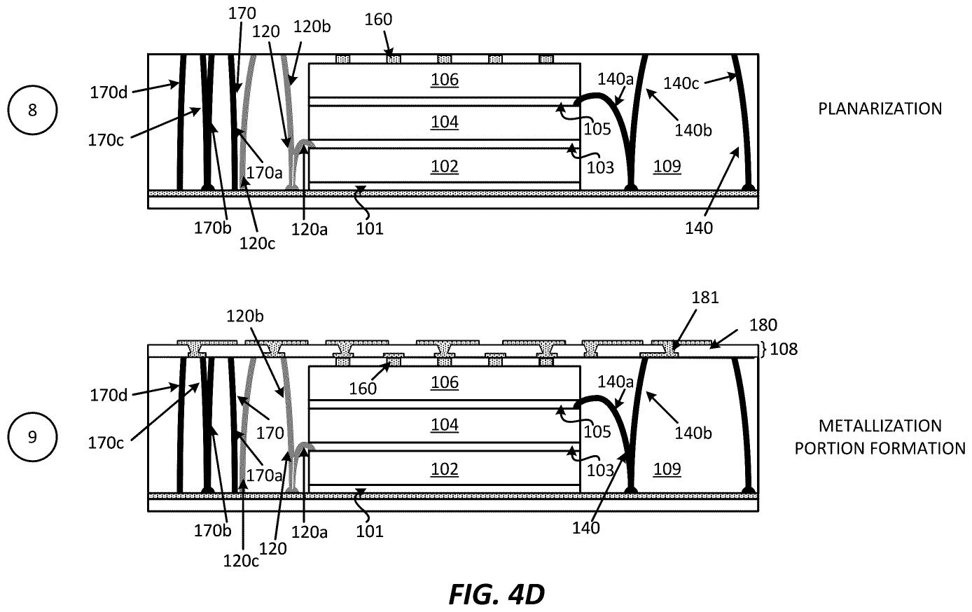

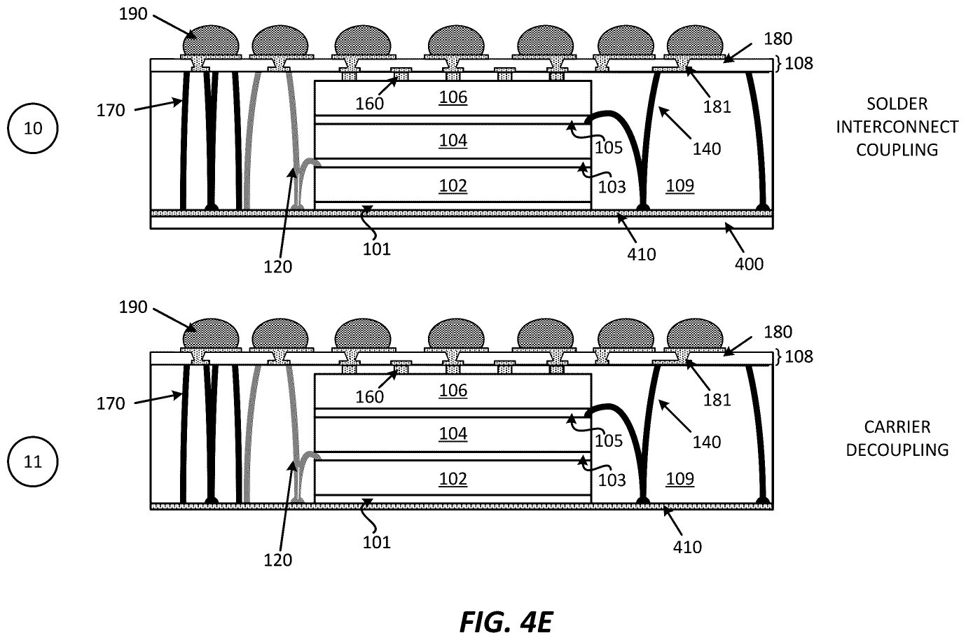

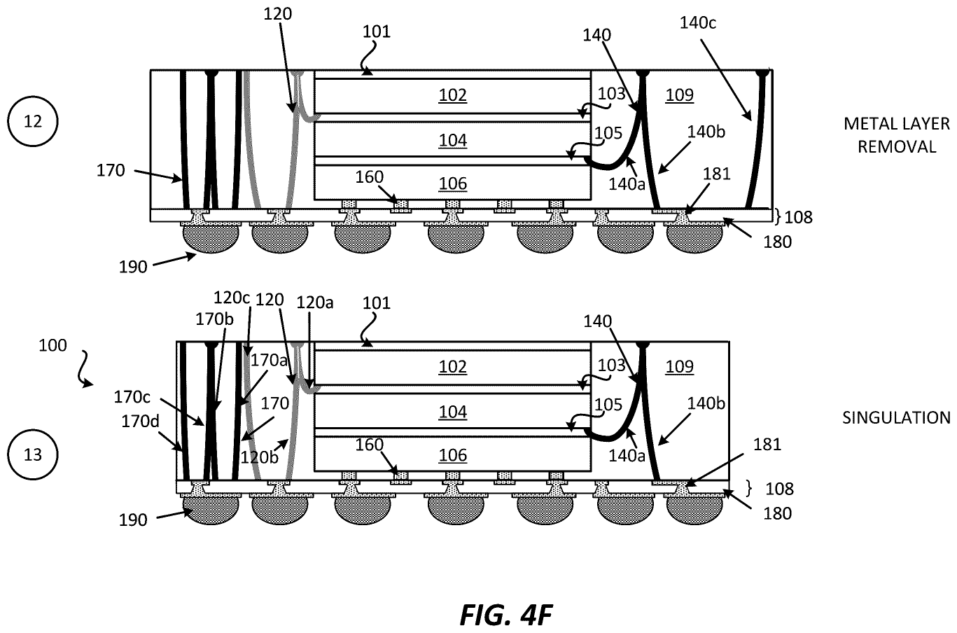

In some implementations, fabricating a package includes several processes. FIGS. 4A-4F illustrate an exemplary sequence for providing or fabricating a package. In some implementations, the sequence of FIGS. 4A-4F may be used to provide or fabricate the package 100. However, the process of FIGS. 4A-4F may be used to fabricate any of the packages described in the disclosure.

It should be noted that the sequence of FIGS. 4A-4F may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1, as shown in FIG. 4A, illustrates a state after a carrier 400 and a metal layer 410 are provided. The carrier 400 may include glass or silicon. Different implementations may use different materials for the carrier 400. The metal layer 410 may be formed on the carrier 400 through a sputtering process. The metal layer 410 may include a seed layer.

Stage 2 of FIG. 4A through stage 6 of FIG. 4C, illustrate states after a plurality of integrated devices are couple to the carrier 400 and the metal layer 410 and after a plurality of wire bonds are coupled to the integrated devices and the metal layer 410.

Stage 2 illustrates a state after the integrated device 102 is coupled to the metal layer 410 through the adhesive 101. A back side of the integrated device 102 may be coupled to the metal layer 410 through the adhesive 401.

Stage 3 illustrates a state after a plurality of wire bonds 420 are formed and coupled to the integrated device 102 and the metal layer 410 through a wire bonding process. The plurality of wire bonds 120 may be coupled to pads of the front side of the integrated device 102. The plurality of wire bonds 120 may be formed from the integrated device 102 to a first portion of the metal layer 410 and then to a second portion of the metal layer 410. In some implementations, the plurality of wire bonds 120 may be formed from a second portion of the metal layer 410 to a first portion of the metal layer 410 and then to the integrated device 102.

Stage 3 also illustrates a state after a plurality of wire bonds 170 are formed and coupled to the metal layer 410. A wire bonding process may be used to form the plurality of wire bonds 170.

Stage 4, as shown in FIG. 4B, illustrates a state after an integrated device 104 is coupled to the integrated device 102 through the adhesive 103. For example, the backside of the integrated device 104 may be coupled to the front side of the integrated device 102 through the adhesive 103. The adhesive 103 may encapsulate part of the plurality of wire bonds 120 located between the integrated device 102 and the integrated device 104.

Stage 5 illustrate a state after a plurality of wire bonds 140 are formed and coupled to the integrated device 104 and the metal layer 410 through a wire bonding process. The plurality of wire bonds 140 may be coupled to pads of the front side of the integrated device 104. The plurality of wire bonds 140 may be formed from the integrated device 104 to a portion of the metal layer 410 and then to another portion of the metal layer 410. In some implementations, the plurality of wire bonds 140 may be formed from a portion of the metal layer 410 to another portion of the metal layer 410 and then to the integrated device 104.

Stage 6, as shown in FIG. 4C, illustrates a state after an integrated device 106 is coupled to the integrated device 104 through the adhesive 105. For example, the backside of the integrated device 106 may be coupled to the front side of the integrated device 104 through the adhesive 105. The adhesive 105 may encapsulate part of the plurality of wire bonds 140 located between the integrated device 104 and the integrated device 106. The integrated device 106 may include a plurality of pillar interconnects 160.

Stage 7 illustrates a state after an encapsulation layer 109 is provided and coupled to the carrier 400 and the metal layer 410. The encapsulation layer 109 may at least partially encapsulate the integrated device 102, the integrated device 104, the integrated device 106, the adhesive 101, the adhesive 103, the adhesive 105, the plurality of wire bonds 120, the plurality of wire bonds 140, the plurality of wire bonds 170 and/or the plurality of pillar interconnects 160. The encapsulation layer 109 may include a mold, a resin, an epoxy and/or a filler. The encapsulation layer 109 may be provided by using a compression and transfer molding process, a sheet molding process, or a liquid molding process. The encapsulation layer 109 may be over molded.

Stage 8, as shown in FIG. 4D, illustrates a state after a planarization process of the encapsulation layer 109. A portion of the encapsulation layer 109, a portion of the plurality of wire bonds 120, a portion of the plurality of wire bonds 140, a portion of the plurality of wire bonds 170 and/or a portion of the plurality of pillar interconnects 160 may be removed and/or grinded off. The planarization process may separate and/or form wire bonds into several wire bonds. For example, after planarization, a wire bond 120a and a wire bond 120b may be defined from the plurality of wire bonds 120. Similar other separate wire bonds may also be formed from the plurality of wire bonds 140 and/or the plurality of wire bonds 170.

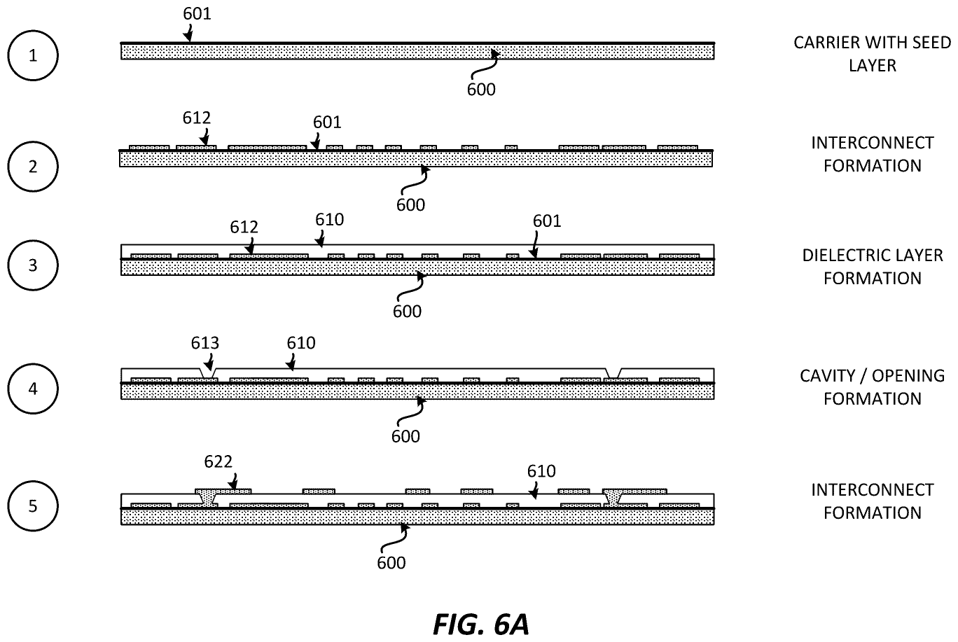

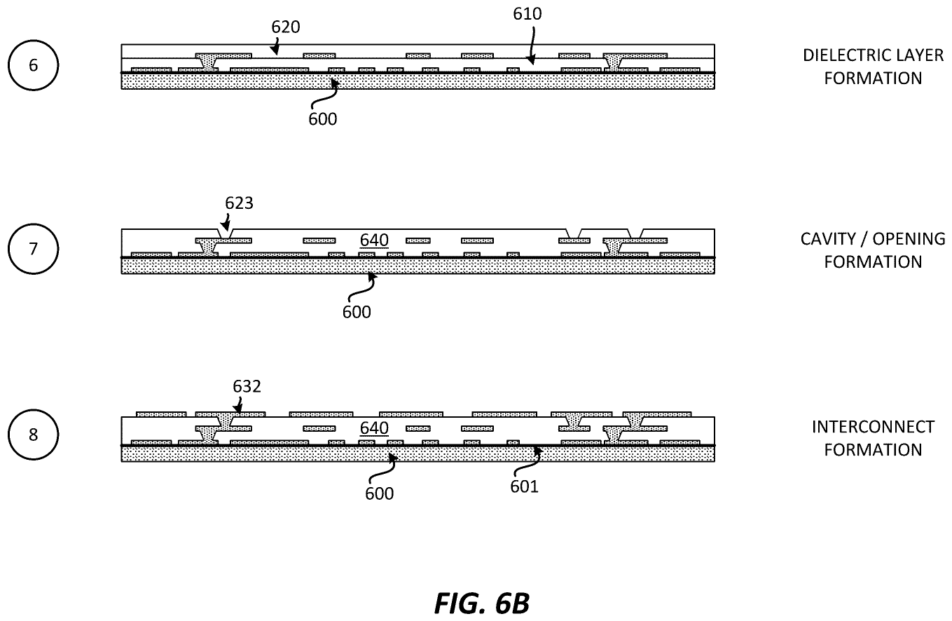

Stage 9 illustrates a state after a metallization portion 108 is formed and coupled to the encapsulation layer 109, the plurality of wire bonds 120, the plurality of wire bonds 140, the plurality of wire bonds 170 and the plurality of pillar interconnects 160. The metallization portion 108 may include at least one dielectric layer 180 and a plurality of metallization interconnects 181. The plurality of metallization interconnects 181 may be formed and coupled to the plurality of wire bonds (e.g., 120, 140, 170) and the plurality of pillar interconnects 160. In some implementations, a deposition process, a lamination process, an etching process (e.g., photo etching process), a laser process, an exposure process, a development process, a lithography process, a plating process, and/or a strip process may be used to form the metallization portion 108. An example of forming a metallization portion is illustrated and described below in at least FIGS. 6A-6B.

Stage 10, as shown in FIG. 4E, illustrates a state after a plurality of solder interconnects 190 are coupled to the plurality of metallization interconnects 181. A solder reflow process may be used to couple the plurality of solder interconnects 190 to the plurality of metallization interconnects 181.

Stage 11 illustrates a state after the carrier 400 is detached from the metal layer 410. The carrier 400 may be detached or grinded off from the metal layer 410.

Stage 12, as shown in FIG. 4F, illustrates a state after the metal layer 410 is removed. The metal layer 410 may be grinded off.

Stage 13 illustrates a state after singulation to form individual packages (e.g., 100) that includes a stack of integrated devices, a plurality of wire bonds, an encapsulation layer and a plurality of pillar interconnects. A saw process may be used for the singulation process. The singulation process may remove some wire bonds from the plurality of wire bonds. For example, some wire bonds from the plurality of wire bonds 120 and/or from the plurality of wire bonds 140 may be removed. Stage 13 may illustrates the package 100.

### Exemplary Flow Diagram of a Method for Fabricating a Package Comprising a Stack of Integrated Devices and Wire Bonds

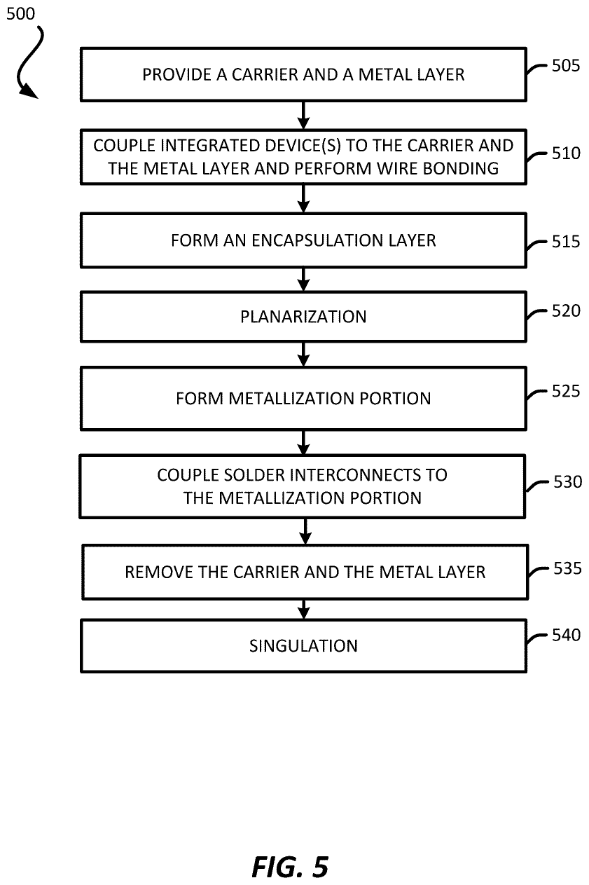

In some implementations, fabricating a package includes several processes. FIG. 5 illustrates an exemplary flow diagram of a method 500 for providing or fabricating a package. In some implementations, the method 500 of FIG. 5 may be used to provide or fabricate the package 100 described in the disclosure. However, the method 500 may be used to provide or fabricate any of the packages described in the disclosure.

It should be noted that the method 500 of FIG. 5 may combine one or more processes in order to simplify and/or clarify the method for providing or fabricating a package. In some implementations, the order of the processes may be changed or modified.

The method provides (at 505) a carrier and a metal layer. Stage 1 of FIG. 4A, illustrates and describes an example of a state after a carrier 400 and a metal layer 410 are provided. The carrier 400 may include glass or silicon. Different implementations may use different materials for the carrier 400. The metal layer 410 may be formed on the carrier 400 through a sputtering process. The metal layer 410 may include a seed layer.

The method couples (at 510) a plurality of integrated devices and forms (at 510) a plurality of wire bonds to the carrier and the metal layer, where some of the integrated devices are stacked on top of each other. Stage 2 of FIG. 4A through stage 6 of FIG. 4C, illustrate and describe examples of states after a plurality of integrated devices are couple to the carrier 400 and the metal layer 410 and after a plurality of wire bonds are coupled to the integrated devices and the metal layer 410.

Stage 2 illustrates a state after the integrated device 102 is coupled to the metal layer 410 through the adhesive 101. A back side of the integrated device 102 may be coupled to the metal layer 410 through the adhesive 401.

Stage 3 illustrates a state after a plurality of wire bonds 420 are formed and coupled to the integrated device 102 and the metal layer 410 through a wire bonding process. The plurality of wire bonds 120 may be coupled to pads of the front side of the integrated device 102. The plurality of wire bonds 120 may be formed from the integrated device 102 to a first portion of the metal layer 410 and then to a second portion of the metal layer 410. In some implementations, the plurality of wire bonds 120 may be formed from a second portion of the metal layer 410 to a first portion of the metal layer 410 and then to the integrated device 102.

Stage 3 also illustrates a state after a plurality of wire bonds 170 are formed and coupled to the metal layer 410. A wire bonding process may be used to form the plurality of wire bonds 170.

Stage 4, as shown in FIG. 4B, illustrates a state after an integrated device 104 is coupled to the integrated device 102 through the adhesive 103. For example, the backside of the integrated device 104 may be coupled to the front side of the integrated device 102 through the adhesive 103. The adhesive 103 may encapsulate part of the plurality of wire bonds 120 located between the integrated device 102 and the integrated device 104.

Stage 5 illustrates a state after a plurality of wire bonds 140 are formed and coupled to the integrated device 104 and the metal layer 410 through a wire bonding process. The plurality of wire bonds 140 may be coupled to pads of the front side of the integrated device 104. The plurality of wire bonds 140 may be formed from the integrated device 104 to a portion of the metal layer 410 and then to another portion of the metal layer 410. In some implementations, the plurality of wire bonds 140 may be formed from a portion of the metal layer 410 to another portion of the metal layer 410 and then to the integrated device 104.

Stage 6, as shown in FIG. 4C, illustrates a state after an integrated device 106 is coupled to the integrated device 104 through the adhesive 105. For example, the backside of the integrated device 106 may be coupled to the front side of the integrated device 104 through the adhesive 105. The adhesive 105 may encapsulate part of the plurality of wire bonds 140 located between the integrated device 104 and the integrated device 106. The integrated device 106 may include a plurality of pillar interconnects 160.

The method forms (at 515) forms an encapsulation layer that at least partially encapsulates the plurality of integrated devices and the plurality of wire bonds. Stage 7, of FIG. 4C, illustrates and describes an example of a state after an encapsulation layer 109 is provided and coupled to the carrier 400 and the metal layer 410. The encapsulation layer 109 may at least partially encapsulate the integrated device 102, the integrated device 104, the integrated device 106, the adhesive 101, the adhesive 103, the adhesive 105, the plurality of wire bonds 120, the plurality of wire bonds 140, the plurality of wire bonds 170 and/or the plurality of pillar interconnects 160. The encapsulation layer 109 may include a mold, a resin, an epoxy and/or a filler. The encapsulation layer 109 may be provided by using a compression and transfer molding process, a sheet molding process, or a liquid molding process. The encapsulation layer 109 may be over molded.

The method planarizes (at 520) the encapsulation layer. Stage 8 of FIG. 4D, illustrates and describes an example of a state after a planarization process of the encapsulation layer 109. A portion of the encapsulation layer 109, a portion of the plurality of wire bonds 120, a portion of the plurality of wire bonds 140, a portion of the plurality of wire bonds 170 and/or a portion of the plurality of pillar interconnects 160 may be removed and/or grinded off. The planarization process may separate and/or form wire bonds into several wire bonds. For example, after planarization, a wire bond 120a and a wire bond 120b may be defined from the plurality of wire bonds 120. Similar other separate wire bonds may also be formed from the plurality of wire bonds 140 and/or the plurality of wire bonds 170.

The method forms (at 525) a metallization portion. Stage 9 of FIG. 4D, illustrates and describes an example of a state after a metallization portion 108 is formed and coupled to the encapsulation layer 109, the plurality of wire bonds 120, the plurality of wire bonds 140, the plurality of wire bonds 170 and the plurality of pillar interconnects 160. The metallization portion 108 may include at least one dielectric layer 180 and a plurality of metallization interconnects 181. The plurality of metallization interconnects 181 may be formed and coupled to the plurality of wire bonds (e.g., 120, 140, 170) and the plurality of pillar interconnects 160. In some implementations, a deposition process, a lamination process, an etching process (e.g., photo etching process), a laser process, an exposure process, a development process, a lithography process, a plating process, and/or a strip process may be used to form the metallization portion 108. An example of forming a metallization portion is illustrated and described below in at least FIGS. 6A-6B.

The method couples (at 530) a plurality of solder interconnects to the metallization portion. Stage 10 of FIG. 4E, illustrates and describes an example of a state after a plurality of solder interconnects 190 are coupled to the plurality of metallization interconnects 181. A solder reflow process may be used to couple the plurality of solder interconnects 190 to the plurality of metallization interconnects 181.

The method removes (at 535) removes the carrier and the metal layer. Stage 11 of FIG. 4E, illustrates and describes an example of a state after the carrier 400 is detached from the metal layer 410. The carrier 400 may be detached or grinded off from the metal layer 410. Stage 12 of FIG. 4F, illustrates and describes an example of a state after the metal layer 410 is removed. The metal layer 410 may be grinded off.

The method singulates (at 540) a wafer to form individual packages. Stage 13 of FIG. 4F, illustrates and describes an example of a state after singulation to form individual packages (e.g., 100) that includes a stack of integrated devices, a plurality of wire bonds, an encapsulation layer and a plurality of pillar interconnects. A saw process may be used for the singulation process. The singulation process may remove some wire bonds from the plurality of wire bonds. For example, some wire bonds from the plurality of wire bonds 120 and/or from the plurality of wire bonds 140 may be removed. Stage 13 may illustrates the package 100.

### Exemplary Sequence for Fabricating a Metallization Portion

In some implementations, fabricating a metallization portion includes several processes. FIGS. 6A-6B illustrate an exemplary sequence for providing or fabricating a metallization portion. In some implementations, the sequence of FIGS. 6A-6B may be used to provide or fabricate the metallization portion 402. However, the process of FIGS. 6A-6B may be used to fabricate any of the metallization portions (e.g., 108) described in

It should be noted that the sequence of FIGS. 6A-6B may combine one or more stages in order to simplify and/or clarify the sequence for providing or fabricating a metallization portion. In some implementations, the order of the processes may be changed or modified. In some implementations, one or more of processes may be replaced or substituted without departing from the scope of the disclosure.

Stage 1, as shown in FIG. 6A, illustrates a state after a carrier 600 is provided. A seed layer 601 may be located over the carrier 600. The carrier 600 may be replaced with other components and/or materials.

Stage 2 illustrates a state after a plurality of interconnects 612 are formed. The interconnects 612 may be located over the seed layer 601. A lithography process, a plating process, a strip process and/or an etching process may be used to form the plurality of interconnects 612. The interconnects 612 may represent at least some of the interconnects from the plurality of metallization interconnects 181.

Stage 3 illustrates a state after a dielectric layer 610 is formed over the carrier 600, the seed layer 601 and the plurality of interconnects 612. A deposition and/or lamination process may be used to form the dielectric layer 610. The dielectric layer 610 may include prepreg and/or polyimide. The dielectric layer 610 may include a photo-imageable dielectric. However, different implementations may use different materials for the dielectric layer.

Stage 4 illustrates a state after a plurality of cavities 613 is formed in the dielectric layer 610. The plurality of cavities 613 may be formed using an etching process (e.g., photo etching process), a laser process, an exposure process and/or a development process.

Stage 5 illustrates a state after interconnects 622 are formed in and over the dielectric layer 610, including in and over the plurality of cavities 613. For example, a via, pad and/or traces may be formed. A lithography process, a plating process, a strip process and/or an etching process may be used to form the interconnects.

Stage 6, as shown in FIG. 6B, illustrates a state after a dielectric layer 620 is formed over the dielectric layer 610 and the plurality of interconnects 622. A deposition and/or lamination process may be used to form the dielectric layer 620. The dielectric layer 620 may include prepreg and/or polyimide. The dielectric layer 620 may include a photo-imageable dielectric. However, different implementations may use different materials for the dielectric layer.

Stage 7, illustrates a state after a plurality of cavities 623 is formed in the dielectric layer 640. The dielectric layer 640 may represent the dielectric layer 610 and/or the dielectric layer 620. The plurality of cavities 623 may be formed using an etching process (e.g., photo etching process), a laser process, an exposure process and/or a development process.

Stage 8 illustrates a state after interconnects 632 are formed in and over the dielectric layer 640, including in and over the plurality of cavities 623. For example, a via, pad and/or traces may be formed. A lithography process, a plating process, a strip process and/or an etching process may be used to form the interconnects.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Flow Diagram of a Method for Fabricating a Metallization Portion

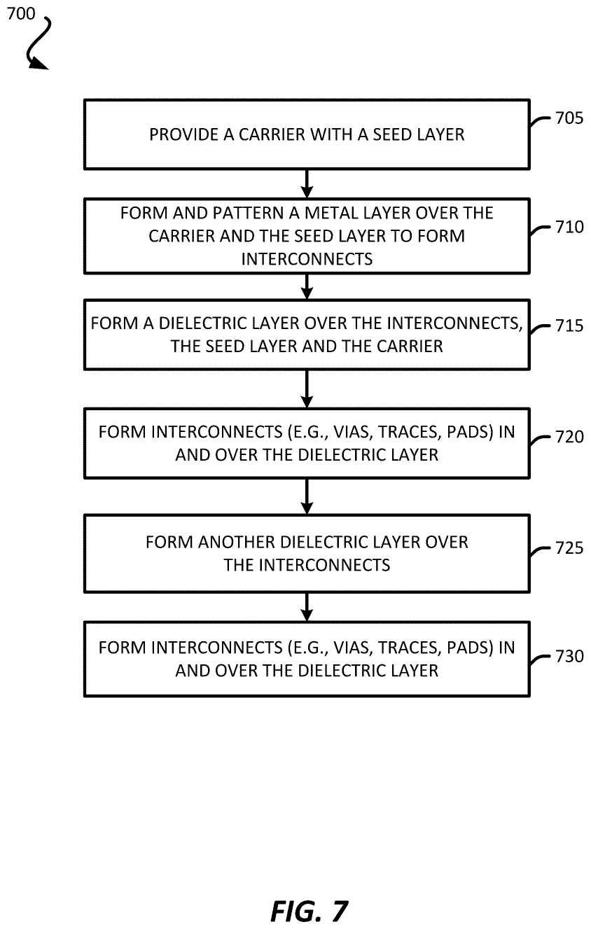

In some implementations, fabricating a metallization portion includes several processes. FIG. 7 illustrates an exemplary flow diagram of a method 700 for providing or fabricating a metallization portion. In some implementations, the method 700 of FIG. 7 may be used to provide or fabricate the metallization portion(s) of the disclosure. For example, the method 700 of FIG. 7 may be used to fabricate the metallization portion 108.

It should be noted that the method 700 of FIG. 7 may combine one or more processes in order to simplify and/or clarify the method for providing or fabricating a metallization portion. In some implementations, the order of the processes may be changed or modified.

The method provides (at 705) a carrier with a seed layer. Stage 1 of FIG. 6A, illustrates and describes an example of a state after a carrier 600 is provided. A seed layer 601 may be located over the carrier 600. The carrier 600 may be replaced with other components and/or materials.

The method forms and patterns (at 710) a plurality of interconnects. Stage 2 of FIG. 6A, illustrates and describes an example of a state after a plurality of interconnects 612 are formed. The interconnects 612 may be located over the seed layer 601. A lithography process, a plating process, a strip process and/or an etching process may be used to form the plurality of interconnects 612. The interconnects 612 may represent at least some of the interconnects from the plurality of metallization interconnects 181.

The method forms (at 710) a dielectric layer. Stage 3 of FIG. 6A, illustrates and describes an example of a state after a dielectric layer 610 is formed over the carrier 600, the seed layer 601 and the plurality of interconnects 612. A deposition and/or lamination process may be used to form the dielectric layer 610. The dielectric layer 610 may include prepreg and/or polyimide. The dielectric layer 610 may include a photo-imageable dielectric. However, different implementations may use different materials for the dielectric layer.

The method forms (at 720) a plurality of interconnects. Forming a plurality of interconnects may including forming a plurality of cavities in a dielectric layer and a performing a plating process. Stage 4 of FIG. 6A, illustrates and describes an example of a state after a plurality of cavities 613 is formed in the dielectric layer 610. The plurality of cavities 613 may be formed using an etching process (e.g., photo etching process), a laser process, an exposure process and/or a development process.

Stage 5 of FIG. 6A, illustrates and describes an example of a state after interconnects 622 are formed in and over the dielectric layer 610, including in and over the plurality of cavities 613. For example, a via, pad and/or traces may be formed. A lithography process, a plating process, a strip process and/or an etching process may be used to form the interconnects.

The method forms (at 725) another dielectric layer. Stage 6 of FIG. 6B, illustrates and describes an example of a state after a dielectric layer 620 is formed over the dielectric layer 610 and the plurality of interconnects 622. A deposition and/or lamination process may be used to form the dielectric layer 620. The dielectric layer 620 may include prepreg and/or polyimide. The dielectric layer 620 may include a photo-imageable dielectric. However, different implementations may use different materials for the dielectric layer.

The method forms (at 730) a plurality of interconnects. Forming a plurality of interconnects may including forming a plurality of cavities in a dielectric layer and a performing a plating process. Stage 7 of FIG. 6B, illustrates and describes an example of a state after a plurality of cavities 623 is formed in the dielectric layer 640. The dielectric layer 640 may represent the dielectric layer 610 and/or the dielectric layer 620. The plurality of cavities 623 may be formed using an etching process (e.g., photo etching process), a laser process, an exposure process and/or a development process.

Stage 8 of FIG. 6B, illustrates and describes an example of a state after interconnects 632 are formed in and over the dielectric layer 640, including in and over the plurality of cavities 623. For example, a via, pad and/or traces may be formed. A lithography process, a plating process, a strip process and/or an etching process may be used to form the interconnects.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Electronic Devices

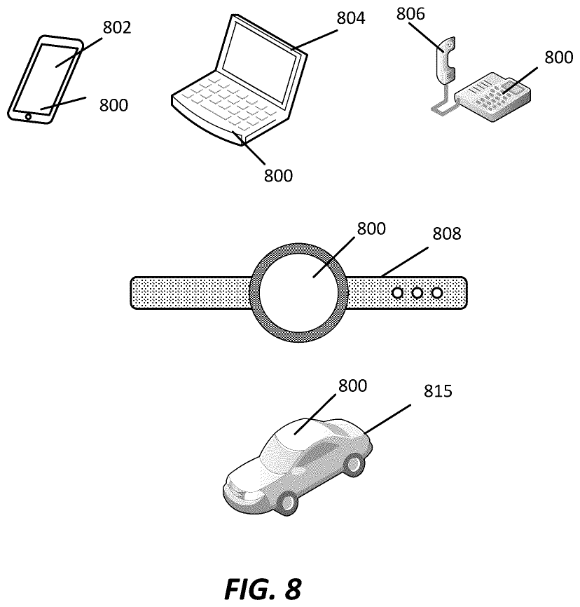

FIG. 8 illustrates various electronic devices that may be integrated with any of the aforementioned device, integrated device, integrated circuit (IC) package, integrated circuit (IC) device, semiconductor device, integrated circuit, die, interposer, package, package-on-package (PoP), System in Package (SiP), or System on Chip (SoC). For example, a mobile phone device 802, a laptop computer device 804, a fixed location terminal device 806, a wearable device 808, or automotive vehicle 810 may include a device 800 as described herein. The device 800 may be, for example, any of the devices and/or integrated circuit (IC) packages described herein. The devices 802, 804, 806 and 808 and the vehicle 810 illustrated in FIG. 8 are merely exemplary. Other electronic devices may also feature the device 800 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-3, 4A-4F, 5, 6A-6B, and 7-8 may be rearranged and/or combined into a single component, process, feature or function or embodied in several components, processes, or functions. Additional elements, components, processes, and/or functions may also be added without departing from the disclosure. It should also be noted FIGS. 1-3, 4A-4F, 5, 6A-6B, and 7-8 and its corresponding description in the present disclosure is not limited to dies and/or ICs. In some implementations, FIGS. 1-3, 4A-4F, 5, 6A-6B, and 7-8 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace (e.g., trace interconnect), a via (e.g., via interconnect), a pad (e.g., pad interconnect), a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.

Aspect 1: A package comprising a metallization portion; a first integrated device coupled to the metallization; a second integrated device coupled to the first integrated device through an adhesive; a first plurality of wire bonds coupled to the second integrated device and the metallization portion; and an encapsulation layer at least partially encapsulating the first integrated device, the second integrated device and the first plurality of wire bonds.

Aspect 2: The package of aspect 1, wherein the first integrated device includes a first front side and a first back side, wherein the second integrated device includes a second front side and a second back side, and wherein the adhesive that couples the first integrated device and the second integrated device touches the first back side of the first integrated device and the second front side of the second integrated device.

Aspect 3: The package of aspect 2, wherein the first plurality of wire bonds are coupled to the second front side of the second integrated device.

Aspect 4: The package of aspects 1 through 3, further comprising a third integrated device coupled to the second integrated device through a second adhesive; and a second plurality of wire bonds coupled to the third integrated device and the metallization portion.

Aspect 5: The package of aspect 4, wherein the encapsulation layer at least partially encapsulates the third integrated device and the second plurality of wire bonds.

Aspect 6: The package of aspect 4, wherein the third integrated device includes a third front side and a third back side, and wherein the second adhesive that couples the second integrated device and the third integrated device touches the second back side of the second integrated device and the third front side of the third integrated device.

Aspect 7: The package of aspect 4, wherein the second plurality of wire bonds are coupled to the third front side of the third integrated device.

Aspect 8: The package of aspect 1 through 7, wherein an electrical path between the first integrated device and the metallization portion includes a plurality of pillar interconnects.

Aspect 9: The package of aspects 1 through 8, wherein an electrical path between the first integrated device and the metallization portion bypasses any wire bond.

Aspect 10: The package of aspects 1 through 3, further comprising a second adhesive coupled to a back side of the second integrated device.

Aspect 11: The package of aspects 1 through 10, wherein the metallization portion comprises at least one dielectric layer; and a plurality of metallization interconnects, wherein the plurality of metallization interconnects are coupled to the first plurality of wire bonds and a plurality of pillar interconnects.

Aspect 12: The package of aspects 1 through 11, wherein the first plurality of wire bonds include a first wire bond that extends (i) from the second integrated device to a first side of the encapsulation layer, and (ii) from the first side of the encapsulation layer to a second side of the encapsulation layer, wherein the second side of the encapsulation layer is opposite to the first side of the encapsulation layer.

Aspect 13: The package of aspects 1 through 12, wherein the adhesive include a die attach film (DAF).

Aspect 14: The package of aspects 1 through 13, wherein the first plurality of wire bonds include a first wire bond that is free of any electrical connection with any integrated device.

Aspect 15: The package of aspects 1 through 14, wherein the first integrated device and the second integrated device are part of a stack of integrated devices.

Aspect 16: The package of aspects 1 through 15, wherein the first integrated device includes a processor device and the second integrated device includes a memory die.

Aspect 17: The package of aspects 1 through 16, wherein an electrical connection between the first integrated device and the metallization portion is free of solder.

Aspect 18: A method for fabricating a package. The method provides a first integrated device. The method couples a second integrated device to the first integrated device through an adhesive. The method couples a first plurality of wire bonds to the second integrated device. The method forms an encapsulation layer that least partially encapsulates the first integrated device, the second integrated and the first plurality of wire bonds. The method forms a metallization portion that is coupled to the first integrated device and the first plurality of wire bonds.

Aspect 19: The method of aspect 18, wherein the first integrated device is coupled to the metallization portion through a plurality of pillar interconnects.

Aspect 20: The method of aspect 19, wherein forming the metallization portion comprises forming at least one dielectric layer; and forming a plurality of metallization interconnects, wherein the plurality of metallization interconnects are coupled to the first plurality of wire bonds and the plurality of pillar interconnects.

Aspect 21: The package of aspects 1 through 17, wherein the package is implemented in a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A package comprising:
a metallization portion;
a first integrated device coupled to the metallization;
a second integrated device coupled to the first integrated device through an adhesive;
a first plurality of wire bonds coupled to the second integrated device and the metallization portion; and
an encapsulation layer at least partially encapsulating the first integrated device, the second integrated device and the first plurality of wire bonds.

2. The package of claim 1,
wherein the first integrated device includes a first front side and a first back side,
wherein the second integrated device includes a second front side and a second back side, and
wherein the adhesive that couples the first integrated device and the second integrated device, touches the first back side of the first integrated device and the second front side of the second integrated device.

3. The package of claim 2, wherein the first plurality of wire bonds are coupled to the second front side of the second integrated device.

4. The package of claim 1, further comprising:
a third integrated device coupled to the second integrated device through a second adhesive; and
a second plurality of wire bonds coupled to the third integrated device and the metallization portion.

5. The package of claim 4, wherein the encapsulation layer at least partially encapsulates the third integrated device and the second plurality of wire bonds.

6. The package of claim 4,
wherein the third integrated device includes a third front side and a third back side, and
wherein the second adhesive that couples the second integrated device and the third integrated device, touches the second back side of the second integrated device and the third front side of the third integrated device.

7. The package of claim 4, wherein the second plurality of wire bonds are coupled to the third front side of the third integrated device.

8. The package of claim 1, wherein an electrical path between the first integrated device and the metallization portion includes a plurality of pillar interconnects.

9. The package of claim 1, wherein an electrical path between the first integrated device and the metallization portion bypasses any wire bond.

10. The package of claim 1, further comprising a second adhesive coupled to a back side of the second integrated device.

11. The package of claim 1, wherein the metallization portion comprises:
at least one dielectric layer; and
a plurality of metallization interconnects, wherein the plurality of metallization interconnects are coupled to the first plurality of wire bonds and a plurality of pillar interconnects.

12. The package of claim 1, wherein the first plurality of wire bonds include a first wire bond that extends (i) from the second integrated device to a first side of the encapsulation layer, and (ii) from the first side of the encapsulation layer to a second side of the encapsulation layer, wherein the second side of the encapsulation layer is opposite to the first side of the encapsulation layer.

13. The package of claim 1, wherein the adhesive include a die attach film (DAF).

14. The package of claim 1, wherein the first plurality of wire bonds include a first wire bond that is free of any electrical connection with any integrated device.

15. The package of claim 1, wherein the first integrated device and the second integrated device are part of a stack of integrated devices.

16. The package of claim 1, wherein the first integrated device includes a processor device and the second integrated device includes a memory die.

17. The package of claim 1, wherein an electrical connection between the first integrated device and the metallization portion is free of solder.

18. A method for fabricating a package, comprising:
providing a first integrated device;
coupling a second integrated device to the first integrated device through an adhesive;
coupling a first plurality of wire bonds to the second integrated device;
forming an encapsulation layer that least partially encapsulates the first integrated device, the second integrated and the first plurality of wire bonds; and
forming a metallization portion that is coupled to the first integrated device and the first plurality of wire bonds.

19. The method of claim 18, wherein the first integrated device is coupled to the metallization portion through a plurality of pillar interconnects.

20. The method of claim 19, wherein forming the metallization portion comprises:
forming at least one dielectric layer; and
forming a plurality of metallization interconnects, wherein the plurality of metallization interconnects are coupled to the first plurality of wire bonds and the plurality of pillar interconnects.
